(19) United States
(12) Patent Application Publication
(10) Pub. No.: US 2007/0249148 A1
(43) Pub. Date: Oct. 25, 2007

(54) METHOD FOR PRODUCING A LAYER CONSISTING OF A DOPED SEMICONDUCTOR MATERIAL

(76) Inventors: Ansgar Werner, Dresden (DE); Jan Birnstock, Dresden (DE); Sven Murano, Dresden (DE)

Correspondence Address: SCHMEISER, OLSEN & WATTS, 22 CENTURY HILL DRIVE, SUITE 302, LATHAM, NY, 12110, US

(21) Appl. No.: 11/576,553

(22) PCT Filed: Oct. 4, 2005
(86) PCT No.: PCT/DE05/01761

§ 371 Date: Apr. 3, 2007

(30) Foreign Application Priority Data
Oct. 4, 2004 (EP) 04023606.9

(51) Int. Cl. H01L 21/20

(52) U.S. Cl. 438/503; 257/E21.162

(57) ABSTRACT

The invention concerns a method for depositing a layer consisting of a doped semiconductor material on a substrate, as well as a device for implementing said method. According to said method, the doped semiconductor material contains at least one semiconductor matrix material and at least one doping material. Said method consists in vaporizing a mixture of the semiconductor material(s) and of the doping material(s) using a vaporizing source, then in depositing said mixture on the substrate.

The invention relates to a method for producing a layer of a doped semiconductor material on a substrate by means of deposition, in particular a layer for an organic light-emitting diode, and to an apparatus for carrying out the process, in which process the doped semiconductor material contains at least one semiconductor matrix material and at least one doping material.

### BACKGROUND OF THE INVENTION

Doped layers of this type may be provided, for example, in organic light-emitting diodes (OLEDs). In this context, it is necessary to distinguish between different types of doped layers. Charge carrier transport layers are doped with strong donor compounds or strong acceptor compounds. A considerably higher conductivity of these layers for electrons or holes is produced by means of a charge transfer between matrix material and doping material. This improves the electrical properties of organic light-emitting diodes in that a lower operating voltage is required for a defined brightness. A wide range of further advantages also ensue, for example better charge carrier injection from the electrodes, which means that a wider range of materials is suitable for producing the electrodes. Furthermore, the thicknesses of the layers which have been doped in this way can be varied within a wide range without ohmic losses in the transport layers adversely affecting the performance of the device. For example, the layer thickness can be selected in such a way that the light which is generated in the device is optimally coupled out of the device by constructive interference.

Molar concentrations of from 1:1 to 1:100 are often selected for doped layers of this type. Doped organic semiconductor layers are also used in other organic devices, such as for example organic solar cells or organic TFTs. A doped layer of this type may, for example, consist of a mixture of 4,4,4-tris(3-methylphenylphenylamino)tri-phenylamine (m-MTDATA) and tetrafluoro tetracyano quinodimethane (F4-TCNQ) in a molar ratio of 50:1. A different form of a doped layer of this type may consist of bathophenanthroline (BPhen) and caesium in a molar ratio of, for example, 8:1.

A further type of doping provides for light-emitting dopants to be mixed into a matrix material (Tang et al., J. Appl. Phys. 65, 3610 (1989)). This mixture then forms the light-emitting layer in an organic light-emitting diode. Doped layers of this type generally have a higher luminescence quantum yield and allow the spectrum of the emitted light to be influenced. Doping concentrations of from 1:2 to 1:1000 are frequently selected for doped layers of this type. By way of example, a doped light-emitting layer of this type may consist of 4,4′,4″-tris(N-carbazolyl)-triphenylamine (TCTA) and factris(2-phenylpyridine) iridium (Ir(ppy)3) in a mass ratio of 5:1.

Mixed layers, known as bulk heterojunctions, are used in organic solar cells to achieve a higher quantum yield for the conversion of light into charge carriers (Gebeyehu et al., Solar Energ. Mater. Solar Cells 79, 81 (2003)).

On account of the absorption of light in organic materials, initially an electron-hole pair with a very high bond energy is formed. In pure materials, therefore, it is difficult for this exciton, as it is known, to be split into unbonded charge carriers. Consequently, a mixture of donor-type and acceptor-type materials is used. The exciton is in this case divided by charge transfer from the donor to the acceptor. Doping concentrations of from 1:1 to 1:10 are often selected for doped layers of this type. By way of example, a doped layer of this type may consist of phthalocyanine zinc and fullerene C60 in a molar ratio of 2:1.

Finally, the literature reports that mixed doped layers can be used to increase the stability of organic devices (Shi et al., Appl. Phys. Lett. 70. 1665 (1997)). Mixtures comprising more than two components are also advantageous for some applications of doped semiconductor layers (cf. for example U.S. Pat. No. 6,312,836 B1, U.S. Pat. No. 6,287,712).

When producing organic, doped semiconductor layers, the organic substance is converted into the gas phase and then deposited. In principle, organic substances can pass into the gas phase from either the liquid or the solid phase. In the former case, this is known as evaporation or vaporization, whereas in the latter case it is known as sublimation. For ease of reading, the following text will use these terms synonymously, and they are intended to encompass the formation of a gas or vapour from both the solid and the liquid phase.

Doped organic layers have hitherto been produced by means of coevaporation. In this case, matrix material and doping material are introduced into respective evaporation sources (evaporators) and sublimed at the same time under high-vacuum conditions. The vapour from the two evaporation sources is deposited on a substrate. A defined mixing ratio of the layer which is formed results as a function of the evaporation rates selected, the radiation emission characteristics of the evaporation sources and the geometry of the arrangement.

This method has a number of drawbacks. It is necessary for the evaporation rates of the evaporation sources to be controlled very accurately throughout the entire evaporation process in order to achieve homogeneous doping. Furthermore, the radiation emission characteristics and the arrangement of the evaporation sources have to be such that the ratio of the flow rates of matrix material and dopant is constant over the entire surface of the substrate. This can only be ensured with considerable difficulty in particular for substrates with a large base area. Furthermore, it is necessary to provide an additional evaporator for the dopant for each doped layer when designing an evaporation installation. Not least, the maintenance outlay for an installation of this type is increased considerably. Finally, there is a considerably increased outlay on control engineering for operation of the evaporators.

There are known methods in which light-emitting layers are produced from organic materials, namely doped layers comprising a matrix material and an emitter dopant, by the matrix material for the light-emitting layer and the emitter dopant being jointly converted into the vapour phase with the aid of one evaporation source and then deposited on a substrate. A process of this type is disclosed, for example, in document EP 1 156 536 A2. A similar process is explained in document EP 1 454 736 A2. In this known process, the organic materials which are to be deposited are mixed with a non-sublimable inorganic material and pressed together to form a compacted pellet. The non-sublimable inorganic material is used to control the temperature in the compacted pellet, so that the heat which is supplied during vaporization is concentrated primarily on the top surface of the pellet, whereas the bottom surface of the pellet is kept at a temperature which is at least 100° C. below the temperature of the top surface. Document US 2003/0180457 A1 has described a process for producing a light-emitting component with an electroluminescent layer of a high-purity material. A matrix material for the light-emitting layer and an emitted dopant are likewise deposited with the aid of a common evaporation source.

### THE INVENTION

It is an object of the invention to provide a method for producing a layer of a doped semiconductor material on a substrate by means of deposition, in particular a layer for an organic light-emitting diode, in which the drawbacks of the prior art are overcome.

This object is achieved by a method having the features of the independent claim 1.

Advantageous configurations of the invention form the subject matter of dependent subclaims.

The invention provides a method for producing a layer of a doped semiconductor material of a substrate by means of deposition, in which the doped semiconductor material contains at least one semiconductor matrix material and at least one doping material, and in which a mixture of the at least one semiconductor matrix material and the at least one doping material is converted into a vapour phase with the aid of a vaporization source and then deposited on the substrate. It is possible to use mixtures of two or more materials.

The proposed method simplifies the production of doped layers. The properties of the molecular flows of matrix material and dopant can be identically configured, since both materials are sublimed/vaporized from the same vaporization source. The ratio of the vaporization rates is substantially independent of time, since only the temperature needs to be controlled. Furthermore, it is possible to simplify the design of vaporizer installations used to carry out the process. The outlay entailed by at least one vaporization source is eliminated from planning and operation of the vaporizer installation for producing devices with doped semiconductor layers, in particular producing devices with organic layers, such as organic light-emitting diodes.

The process can be used in combination with various process configurations. For example, in addition to vaporization by the supply of thermal energy, it is also possible to provide for the use of laser light pulses and molecular beam epitaxy.

### DESCRIPTION OF PREFERRED EXEMPLARY EMBODIMENT

The invention is explained in more detail below on the basis of exemplary embodiments.

If the thermal vaporization under vacuum conditions is used to produce a layer of a doped semiconductor material, the material that is to be evaporated is introduced into a crucible made from ceramic, glass, metal or similar substances. The crucible is then heated, with the result that the material to be evaporated is converted into the gas phase. A suitable sublimation rate is established at different temperatures depending on the bond energy of the solid or liquid phase. By way of example, the dopant F4-TCNQ can be evaporated at just 120° C., whereas fallerene C60 can only be evaporated at 400° C.

Surprisingly, it has been discovered that it is nevertheless possible for a mixture of materials to be evaporated with a time-independent ratio of the flow rates of the materials. A number of exemplary embodiments are described below.

### Exemplary Embodiment 1

In an exemplary embodiment, the sublimation/vaporization temperatures of the materials involved differ by less than approximately 50° C., preferably by less than approximately 20° C. In the present context, the sublimation temperature is to be understood as meaning the temperature which is required to set the desired doping concentration in a vaporizer installation in which the matrix material and the dopant are vaporized from two directly adjacent, separate sources with the same surface areas. Since vaporization is a thermally activated process, the vaporization rate increases very considerably as the temperature rises. Consequently, the expectation would be that a mixture of two different materials in a crucible would not lead to simultaneous sublimation/vaporization of the mixture with a time-independent ratio of the flow rates of the materials. Rather, the expectation would be that in this case the more volatile component would pass into the gas phase more quickly, whereas the less volatile component would remain alone in the crucible after the other component has been completely consumed.

A component is less volatile than another component if it has a vaporization/sublimation temperature which is higher than the vaporization/sublimation temperature of the other component.

The behaviour which was discovered when producing the doped material can be explained by the fact that the surface area of a solid, more volatile component, namely the component with the lower sublimation/vaporization temperature, is reduced by the initially faster sublimation/vaporization, so that the sublimation/vaporization rate is reduced until it is in a stable ratio with respect to the sublimation/vaporization rate of the less volatile component.

In some cases, it may be impossible to select the matrix material and dopant in such a way that their sublimation temperatures differ by less than approximately 50° C., advantageously by less than approximately 20° C. This may be the case if a defined, additionally required property of the matrix material or the dopant, such as colour, redox potentials or luminescence quantum efficiency, can only be realized within a limited class of materials. In these cases, further measures are provided to ensure that the ratio of the vaporization rates of matrix material and dopant are constant over the course of time. Other important factors in this context are whether the matrix material is in sold or liquid form at the sublimation temperature and whether a chemical reaction takes place between matrix material and dopant when they are mixed.

Without intending hereby to restrict the scope of the invention, the sublimation can be understood as a thermally activated process in which the molecular flow Φ_{M} of a compound M can be represented as
Φ_{M}=ρ(r,α)·σ_{M}A·νexp(−H_{sub}/kT)

where H_{sub} is the sublimation enthalpy of the material, k is the Boltzmann constant, T is the temperature, ν is a rate constant expressed in the unit 1/s, σ_{M} is the area density of the material at the surface of the entire material to be vaporized and A is the area of the surface. The factor ρ(r,α) describes the dependency of the flow on the distance and angle with respect to the crucible normal, i.e. the vaporizer characteristic.

For a pure material, the area density σ_{M} is equal to the area density of the pure material σ_{M}*, and the area A is equal to the area of the material. For a homogeneous mixture of a plurality of materials, the area density of the material M1 is reduced according to the proportion x₁ of material M1 in the mixture: σ_{M}=x₁σ_{M}*. The area A is then the area of the mixture.

The sublimation enthalpy H_{sub} of a pure material is equal to the sublimation enthalpy H_{sub}* of the pure material. The sublimation enthalpy of a material M in a mixture may deviate considerably from the value H_{sub}*. This depends on the type of mixture and the form of interaction between M and other constituents of the mixture. If the mixture comprises large crystallites of the various materials to be vaporized, a molecule M is substantially surrounded by other molecules M of the same type, and the sublimation enthalpy approximately corresponds to the value for the pure material H_{sub}*. In the case of a very fine mixture with very small crystallites or a completely intimate mixture of the molecules, the sublimation enthalpy of the compound M may differ from the value of the pure material H_{sub}*, since the molecules M now also interact with the other types of molecules in the mixture. In the case of a very strong interaction, the sublimation enthalpy may reach very high levels. This is the case, for example, if molecules M carry out a charge transfer to other molecules of the mixture, forming an organic salt.

In the process according to the invention, the ratios of the molecular flows at defined positions during sublimation from just one crucible are considered. Consequently, the factor σ(r,α) is identical for all the materials in the crucible and is therefore eliminated from forming the ratio. Consequently, this factor requires no further consideration.

To obtain a defined ratio of the flows Φ_{M1}/Φ_{M2} of two materials M1 and M2 in a crucible, it is possible to influence the parameters σ_{M1} and σ_{M2} and the parameters H_{sub1} and H_{sub2}. The temperature, by contrast, is the temperature of the crucible and is therefore equal for all the materials in the crucible.

The area density σ_{M} of a material is defined as the number of molecules M situated at the surface of the crucible filling divided by the area of the total crucible filling. There are various conceivable options for varying the area density. One option consists in reducing the proportion of an excessively volatile component in the mixture which is to be vaporized and in this way reducing the molecular flow at a defined temperature by means of the reduced area density.

In one implementation of the exemplary embodiment described in the above paragraphs, 22 mg of tetracene and 4.3 mg of tetrafluoro-tetracyano-quinodimethane (F4-TCNQ) were introduced as initial charge and jointly placed in a vaporizer with ceramic crucible. Sublimation of the mixture at 140° C. produces a 450 mn thick layer with a conductivity of greater than 5e-8 S/cm. At the end of the vaporization operation, a layer thickness of 50 nm with a lower conductivity is still formed. In the case of sublimation of tetracene or F4-TCNQ in pure form, the sublimation temperatures, for comparison, are 140° C. or 130° C., respectively.

### Exemplary Embodiment 2

A further option, which goes beyond the above description, for reducing the molecular flow of an excessively volatile component in a mixture is to fixedly embed this component in the mixture. This is done, for example, by pressing the mixture. The pressing can be carried out in standard pressing apparatus, as used for example to produce KBr pellets in infrared spectroscopy. In this case, the molecular proportion of the more volatile component is advantageously 50% or less, more advantageously 10% or less. The pressing operation compresses all the pores in the mixture. The more volatile component can accordingly only be sublimed in the extent of its molecules which are currently at the surface. In this case, it is assumed that the mixture does not pass into the liquid phase before or during the sublimation. Since the more volatile component is fixedly incorporated in the less volatile component, the more volatile component can only sublime when its molecules simultaneously reach the surface, i.e. are uncovered, as a result of the sublimation of the less volatile component. In this way, the flow of the more volatile component is determined from the mixing ratio in the mixture and the flow of the less volatile component. In particular, the ratio of the molecular flows corresponds to the mixing ratio of the mixture.

In one implementation of the abovementioned exemplary embodiment, 4.4 g of naphthalene tetracarboxylic dianhydride (NTCDA) and 0.12 g of leuco crystal violet (LCV) were mixed and milled in a ball mill in the absence of light at room temperature. A powder of a light violet colour is obtained. LCV is converted into the crystal violet (CV) cation by irreversible oxidation when it is introduced into an electron-accepting matrix, such as NTCDA. This reaction takes place very slowly in the absence of light and at room temperature. The powder produced by milling is therefore a mixture of LCV with NTCDA in which only a small proportion of the LCV has reacted to form CV.

Some of the powder was pressed in a press at a pressure of 5 tons for three minutes to form a pellet with a diameter of 1 cm and a height of 1 mm. A solid body with a homogeneous dark blue appearance is obtained. The blue colour is not necessarily attributable to further oxidation of LCV to CV, but rather may also be attributable to a high transparency of the pellet formed, and the associated integration of the absorption of the CV cations which have already formed. However, the amount of LCV which has already oxidized in the tablet is of no relevance to the process according to the invention.

A quarter of the pellet obtained was introduced into a commercially available vaporizer with ceramic crucible and deposited on a substrate under high-vacuum conditions at approximately 190° C. In previous experiments, LCV has proven to be a highly volatile substance which sublimes at just 150° C. However, the sublimation temperature of 190° C. which is used corresponds to the empirical value for NTCDA. The layer which is formed is irradiated with the light from a halogen lamp. This leads to activation of the doping process. The conductivities of the layers which are formed are measured continuously.

In a first step, a total layer thickness of 1 μm was deposited, with the conductivity produced in the first 300 nm being greater than 1e-5 S/cm and for the remaining layer thickness being greater than 1e-6 S/cm layers which consist of undoped NTCDA have a conductivity of less than 1e-8 S/cm. It can be concluded from this that the layers formed during the vaporization of the pellet have a homogeneous doping.

In a second step, a further layer thickness of 600 nm was deposited, and the conductivity was in this case too greater than 1e-6 S/cm. Finally, a further 200 nm with a lower conductivity are deposited, until ultimately the pellet has been completely vaporized. For a specimen of LCV:NTCDA produced by means of coevaporation with a doping ratio of 1:50, the conductivity of a freshly prepared layer is approximately 5e-5 S/cm.

### Exemplary Embodiment 3

In a further exemplary embodiment, a chemical reaction takes place between the matrix material and the doping material, so that it is possible for the volatility of the dopant to be very considerably reduced on account of the chemical bonding. For example, if an ionic bond is formed, vaporization would first of all require the formation of neutral molecules by charge back transfer, with these neutral molecules then passing into the gas phase. In this case, a much higher energy is generally required than the energy available at practical sublimation temperatures.

In this case, it is expedient for matrix material and doping material to be mixed by means of only gentle stirring. As a result, the microstructure of matrix material and dopant are retained, so that the chemical reaction only takes place to a small extent at the grain boundaries. It is possible to select the grain sizes of matrix and dopant in such a way that on the one hand chemical reactions are suppressed but on the other hand sufficiently homogeneous mixing can be achieved.

The dependent relationship between the sublimation temperature of the mixture and the strength of the chemical bonding can also be deliberately used to increase the sublimation temperature of the more volatile component. This is the case if the thermal energy at the sublimation temperature of the less volatile component is already sufficient to break the chemical bond between the two components. In the case of mixtures of components in donor and acceptor form, this may be the case if the two components carry out only a partial charge transfer or if the respective ionization potentials and electron affinities with respect to the matrix are not too far apart. The degree of charge transfer can be measured by means of infrared spectroscopy. The ionization potentials and electron affinities can be brought closer together with the aid of the redox potentials of the components involved.

In any case, it is expedient for the two components to be thoroughly mixed before use, for example by means of joint milling in a ball mill or a mortar. Furthermore, it is also possible for a material which becomes liquid below the sublimation temperature and thereby facilitates a chemical reaction between the two components to be selected as the less volatile material.

In a comparative experiment, 44.9 mg of m-MTDATA and 15.5 mg of F4-TCNQ were introduced as initial charge and intensively mixed in a mortar for five minutes. This formed a deep green powder. Based on the initial weighed-quantities, this powder consists of a stochiometric mixture of the two components in a ratio of 1:1. The mixture was heated in a vacuum chamber up to 400° C. without sublimation being observed.

In a further comparative experiment, 0.88 g of m-MTDATA and 6.4 mg of F4-TCNQ were introduced as initial charge and mixed. Based on the initial weighed-in quantities, the mixture has a molecular mixing ratio of m-MTDATA: F4-TCNQ of 50:1. The mixture was vaporized in a vacuum chamber at 193° C. The layer formed had a conductivity of less than 1e-9 S/cm and was therefore undoped.

For p-doped m-MTDATA with a doping ratio of 50:1 produced by means of coevaporation, by contrast, the conductivity is approximately 1e-5 S/cm. There is a complete charge transfer from matrix to dopant.

### Exemplary Embodiment 4

In a further exemplary embodiment, a mixture of two materials which initially pass into the liquid phase below their vaporization temperature is processed. It is also possible for only one material of the mixture to pass into the liquid phase below the evaporation temperature while at least one other remains in the solid phase. Evaporation would then be carried out, for example, from a solution, an emulsion or a dispersion. Given a suitable selection of the matrix and doping materials, it is in this case too possible to achieve a constant ratio of the evaporation rates and correspondingly to achieve the desired doped layer. In a particularly advantageous configuration of the invention, the materials are in the form of an azeotropic mixture in the melt.

When carrying out this exemplary embodiment, 95 mg of TPD and 13.5 mg of F₄-TCNQ were introduced as initial charge and ground together in a ceramic mortar. The resulting powder was introduced into a vaporizer crucible and initially heated to 150° C. In the process, it was observed that a doped layer is already being deposited on the substrate. After about 3 minutes at 150° C., the vaporizer was cooled. Inspection of the vaporizer crucible revealed that the TPD: F4-TCNQ mixture has melted.

In a second step, the vaporizer was heated to 150° C. The conductivity of the layer formed on the substrate was measured. After a run-up phase of 7 minutes, a doped layer with an increased conductivity of over 1e-8 S/cm is formed until the material has been consumed.

The features of the invention disclosed in the present description and the claims may be of importance both individually and in any desired combination for the implementation of the invention in its various embodiments.

1. A method for producing a charge carrier transport layer of a doped charge carrier transport semiconductor material on a substrate by means of deposition, in which the doped charge carrier transport semiconductor material contains at least one semiconductor matrix material and at least one doping material, which increases the electrical conductivity of the semiconductor matrix material for charge carriers, characterized in that a mixture of the at least one semiconductor matrix material and the at least one doping material is converted into a vapour phase with the aid of a vaporization source and is then deposited on the substrate.

2. Method according to claim 1, characterized in that a semiconductor matrix material of relatively low volatility is used for the at least one semiconductor matrix material, so that the volatility of the at least one doping material is greater than the volatility of the at least one semiconductor matrix material.

3. Method according to claim 1, characterized in that a semiconductor matrix material of relatively high volatility is used for the at least one semiconductor matrix material, so that the volatility of the at least one doping material is lower than the volatility of the at least one semiconductor matrix material.

4. Method according to claim 2, characterized in that the vaporization/sublimation temperature of the at least one semiconductor matrix material and the vaporization/sublimation temperature of the at least one doping material differ by less than approximately 50° C., preferably by less than approximately 20° C.

5. Method according to claim 1, characterized in that the molar proportion of the material with the higher volatility in the mixture of the at least one semiconductor matrix material and the at least one doping material is less than approximately 50%, preferably less than approximately 20%.

6. Method according to claim 1, characterized in that the matrix material and/or the doping material are vaporized from the liquid phase.

7. Method according to claim 1, characterized in that the mixture is sublimed from the solid phase.

8. Method according to claim 7, characterized in that the solid mixture is introduced into the vaporization source in the form of a pressed material.

9. Method according to claim 1, characterized in that the at least one semiconductor matrix material and/or the at least one doping material are milled before being introduced into the vaporization source.

10. Method according to claim 1, characterized in that at least some of the at least one semiconductor matrix material and of the at least one doping material chemically react with one another in the vaporization source to form a reaction product, with the result that the volatility of the at least one semiconductor matrix material and/or the at least one doping material is altered, and in that the reaction product is converted in the vaporization source into the at least one semiconductor matrix material and the at least one doping material, so that the at least one semiconductor matrix material and the at least one doping material become gaseous, and then the at least one semiconductor matrix material and the at least one doping material are deposited on the substrate.

11. Method according to claim 10, characterized in that the volatility of the at least one semiconductor matrix material and the volatility of the at least one doping material are brought closer to one another.

12. Method according to claim 1, characterized in that the ratio of the rate at which the at least one semiconductor matrix material is converted into the vapour phase in the vaporization source and the rate at which the at least one doping material is converted into the vapour phase is kept substantially constant.

13. Method according to claim 1, characterized in that the mixture is converted into the vapour phase in the vaporization source by the supply of thermal energy.

14. Method according to claim 1, characterized in that the mixture is converted into the vapour phase in the vaporization source by laser light pulses being radiated in.

15. Method according to claim 1, characterized in that the mixture of the at least one semiconductor matrix material and the at least one doping material is deposited by means of molecular beam epitaxy.
